(19) United States
(12) Patent Application Publication
(10) Pub. No.: US 2007/0111399 A1
(43) Pub. Date: May 17, 2007

(54) Method of fabricating an exposed die package

(76) Inventor: Thomas M. Goida, Windham, NH (US)

Correspondence Address: Iandiorio & Teska, 260 Bear Hill Road, Waltham, MA, 02451-1018, US

(21) Appl. No.: 11/272,962

(22) Filed: Nov. 14, 2005

(51) Int. Cl. H01L 21/00

(52) U.S. Cl. 438/127; 438/106

(57) ABSTRACT

A method of fabricating an exposed die package. A feature on at least one side of the die is formed. The die is placed on a substrate and encapsulated. Then, the die is removed from the substrate to reveal an exposed die surface.

### FIELD OF THE INVENTION

This subject invention relates to electronic circuitry packaging.

### BACKGROUND OF THE INVENTION

Silicon dies containing electronic circuitry are typically mounted in a device package. The backside of the die is bonded to a die pad or paddle and the active circuitry side of the die is wire bonded to a lead frame. A package surrounds and thus protects the die and wire bonds. The leads of the lead frame extend out of the package so this “chip” can be soldered to a circuit board.

U.S. Pat. No. 6,294,100 discloses a process wherein a die is packaged and the backside of the die is left exposed. Such an exposed die has certain advantages in certain implementations.

According to the ′100 patent, a film is applied to the back surface of a lead frame strip and several die are mounted to the film between the leads of the lead frame. This structure is then overmolded with an encapsulant and the film is removed. The resulting structure is then singulated to form separate packages each including a single die.

Such a method, however, does not always provide proper and reliable anchoring of the die within the package. Moreover, there is a moisture path from the outside of the package to the die surface which could lead to long term reliability problems.

### SUMMARY OF THE INVENTION

It is therefore an object of this invention to provide a method of fabricating an exposed die package in which the die is securely and reliably mounted in the package.

It is a further object of this invention to provide such a method which prevents moisture ingress from the outside of the package to the die surface.

It is a further object of this invention to provide such a method which results in a more reliable die package.

It is a further object of this invention to provide such a method which is easy and economical to implement.

It is a further object of this invention to provide an exposed die package which is more reliable.

The subject invention results from the realization that if a feature such as a ledge is formed around the periphery of the die, the encapsulant of the package is now better secured to the die and the resulting tortuous moisture path prevents moisture ingress.

The subject invention, however, in other embodiments, need not achieve all these objectives and the claims hereof should not be limited to structures or methods capable of achieving these objectives.

The subject invention features a method of fabricating an exposed die package. The method includes forming a feature on at least one side of the die, placing the die on a substrate, encapsulating the die, and removing the die from the substrate to reveal an exposed die surface.

In one preferred embodiment, the feature is a ledge around the periphery of the die. Forming the ledge feature includes, at the wafer stage, cutting partially through the wafer back side to produce a first, larger cut. Then, the wafer is cut from the front side to produce a second, smaller cut and to singulate the die from the wafer.

One typical substrate is a polyimide tape. Also, a lead frame can be placed on the substrate and wire bonds employed to connect the die to the lead frame prior to encapsulating.

One preferred method of fabricating an exposed die package includes cutting partially through the back side of a wafer to produce a first, larger cut, cutting through the wafer front side to produce a second, smaller cut and to singulate the die from the wafer, placing the die on a substrate, encapsulating the die, and removing the die from the substrate to reveal an exposed die surface.

One exposed die package in accordance with this invention includes a die with an active circuitry side and a back side, a feature on at least one side of the die, and an encapsulant over the active circuitry side of the die and about the feature leaving the back side of the die exposed to lock the die in the encapsulant and/or to prevent moisture ingress. In one example, the feature is a ledge around the periphery of the die and the encapsulant is under the ledge. The die package may further include a lead frame about the die and wire bonds extending from the active circuitry side of the die to the lead frame. Typically, the encapsulant is disposed about the wire bonds and at least partially covers the lead frame.

An exposed die package in accordance with this invention includes a die with an active circuitry side and a back side, an encapsulant over the active circuitry side of the die but leaving the back side of the die exposed, and means, on the side of the die, for locking the die in the encapsulant and/or for preventing moisture ingress along at least one side of the die. In one example, the means is a ledge around the periphery of the die.

### BRIEF DESCRIPTION OF THE DRAWINGS

Other objects, features and advantages will occur to those skilled in the art from the following description of a preferred embodiment and the accompanying drawings, in which:

FIG. 1 is a schematic cross-sectional view of a prior art exposed die package;

FIGS. 2A-2G are schematic cross-sectional views showing one method of fabricating an exposed die package in accordance with the subject invention;

FIG. 3 is a schematic cross-sectional view showing an example of a die with a locking and moisture ingress prevention feature in accordance with the subject invention; and

FIG. 4 is a schematic cross-sectional view showing another example of a die with a different kind of locking and moisture ingress prevention feature in accordance with the subject invention.

### DISCLOSURE OF THE PREFERRED EMBODIMENT

Aside from the preferred embodiment or embodiments disclosed below, this invention is capable of other embodiments and of being practiced or being carried out in various ways. Thus, it is to be understood that the invention is not limited in its application to the details of construction and the arrangements of components set forth in the following description or illustrated in the drawings. If only one embodiment is described herein, the claims hereof are not to be limited to that embodiment. Moreover, the claims hereof are not to be read restrictively unless there is clear and convincing evidence manifesting a certain exclusion, restriction, or disclaimer.

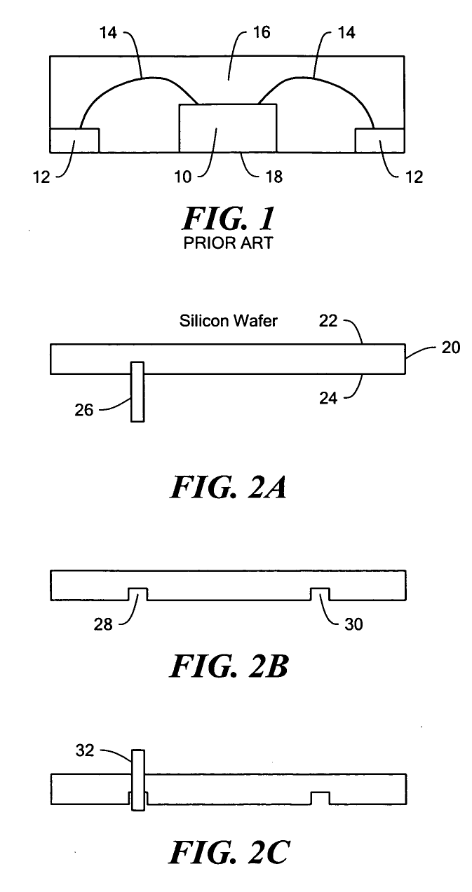

FIG. 1 shows, in cross section, a singulated die package with die 10, lead frame 12, and wire bonds 14 between the active circuitry side of die 10 and lead frame 12 according to U.S. Pat. No. 6,294,100 incorporated herein by this reference. Encapsulant material 16 covers die 10, lead frame 12, and wire bonds 14 but the back side 18 of the die is left exposed. The reason for an exposed back side die is higher I/O pad density, enhanced thermal performance, and also to provide a low package profile. Die 10 is not reliably anchored in encapsulant 16, however, and, moreover, there is a direct moisture path between the die and the encapsulant along the straight featureless sides of die 10 to the interior of the package.

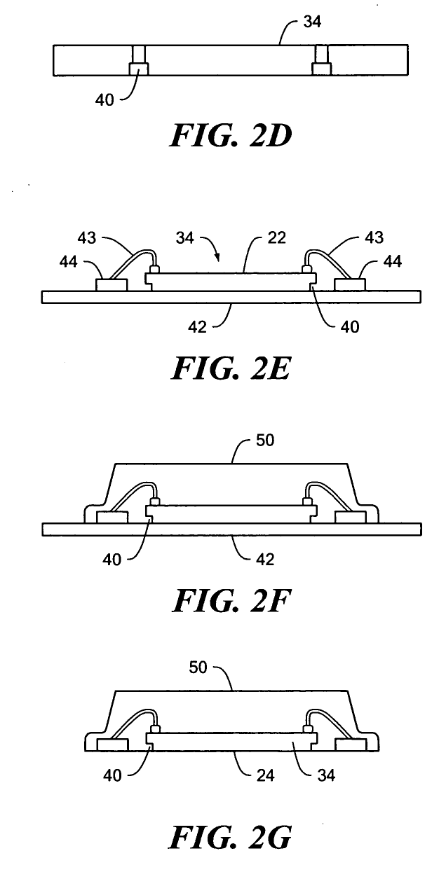

In accordance with one preferred embodiment of the subject invention, silicon wafer 20, FIG. 2A, has active circuitry side 22 and back side 24. A large-kerf wafer saw blade 26 is used to produce partial singulation cuts 28 and 30 from the back side of the wafer as shown in FIG. 2B. Similar cuts are made on the other two sides of each die.

A small-kerf wafer saw blade 32, FIG. 2C is then employed to fully singulate die 34, FIG. 2D, forming feature 40, in this example, a ledge around the periphery of the die. Die 34 is then placed on substrate 42, a polyimide tape for example, FIG. 2E, along with lead frame 44. Wire bonds 43 are then installed between the active circuitry side 22 of die 34 and lead frame 44.

This subassembly is encapsulated (e.g., molded) using an encapsulant 50, FIG. 2F, and the tape 42 is then removed, FIG. 2G. Die 34 is thus packaged in encapsulant 50 but back side 24 is exposed. Other types of encapsulants including, but not limited to, covers for die 34 and the like can also be employed.

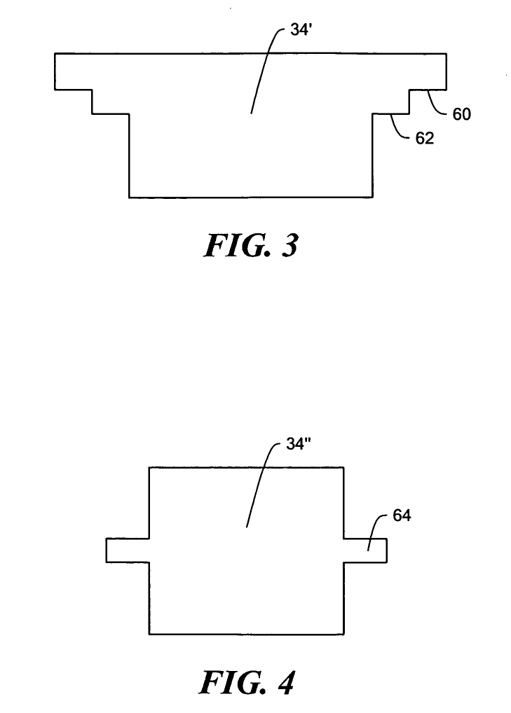

Ledge feature 40 provides a tortuous path and thus prevents moisture ingress. Also, encapsulant material underneath ledge 40 securely locks die 34 within encapsulant 50. A feature in the form of ledge 40 is easy to form but such a feature is not a necessary limitation of the subject invention. For example, in FIG. 3, steps 60 and 62 are formed on the periphery of die 34′. In FIG. 4, the feature is tab 64 around the periphery of die 34″. Other types of ledge type features or means on all four or one or two or three sides of the die which aid in locking the die into the encapsulant and/or prevent moisture ingress are within the scope of the present invention.

The method of the subject invention as, for example, depicted in FIGS. 2A-2G, results in a die securely and reliably mounted within the encapsulant package. Moisture ingress is prevented because of the tortuous path along the sides of the die. The preferred method is easy and economical to implement and the result, in any embodiment, is an exposed die package which is more reliable. A feature such as a ledge is formed in the periphery of the die and an encapsulant material is now better secured to the die and the resulting moisture path is now tortuous to prevent moisture ingress.

Although specific features of the invention are shown in some drawings and not in others, however, this is for convenience only as each feature may be combined with any or all of the other features in accordance with the invention. Also, the words “including”, “comprising”, “having”, and “with” as used herein are to be interpreted broadly and comprehensively and are not limited to any physical interconnection. Moreover, any embodiments disclosed in the subject application are not to be taken as the only possible embodiments. Other embodiments will occur to those skilled in the art and are within the following claims.

In addition, any amendment presented during the prosecution of the patent application for this patent is not a disclaimer of any claim element presented in the application as filed: those skilled in the art cannot reasonably be expected to draft a claim that would literally encompass all possible equivalents, many equivalents will be unforeseeable at the time of the amendment and are beyond a fair interpretation of what is to be surrendered (if anything), the rationale underlying the amendment may bear no more than a tangential relation to many equivalents, and/or there are many other reasons the applicant can not be expected to describe certain insubstantial substitutes for any claim element amended.

What is claimed is:

1. A method of fabricating an exposed die package, the method comprising:
forming a feature on at least one side of the die;
placing the die on a substrate;
encapsulating the die; and
removing the die from the substrate to reveal an exposed die surface.

2. The method of claim 1 in which the feature is a ledge around the periphery of the die.

3. The method of claim 2 in which forming the ledge feature includes, at the wafer stage, cutting partially through the wafer back side to produce a first, larger cut.

4. The method of claim 3 in which forming the ledge further includes cutting through the wafer front side to produce a second, smaller cut and to singulate the die from the wafer.

5. The method of claim 1 in which the substrate is a polyimide tape.

6. The method of claim 1 further including the step of assembling a lead frame on the substrate and wire bonding the die to the lead frame prior to encapsulating.

7. A method of fabricating an exposed die package, the method comprising:
cutting partially through the back side of a wafer to produce a first, larger cut;
cutting through the wafer front side to produce a second, smaller cut and to singulate the die from the wafer;
placing the die on a substrate;
encapsulating the die; and
removing the die from the substrate to reveal an exposed die surface.

8. The method of claim 7 further including the step of assembling a lead frame on the substrate and wire bonding the die to the lead from prior to encapsulating.

9. A method of fabricating an exposed die package, the method comprising:
forming a feature on at least one side of the die;
placing the die on a substrate;
assembling a lead frame on the substrate around the die;
wire bonding the die to the lead frame;
encapsulating the die and the wire bonds; and
removing the die from the substrate to reveal an exposed die surface.

10. The method of claim 9 in which the feature is a ledge around the periphery of the die.

11. The method of claim 10 in which forming the ledge feature includes, at the wafer stage, cutting partially through the wafer back side to produce a first, larger cut.

12. The method of claim 11 in which forming the ledge further includes cutting through the wafer front side to produce a second, smaller cut and to singulate the die from the wafer.

13. An exposed die package comprising:
a die with an active circuitry side and a back side;
a feature on at least one side of the die; and
an encapsulant over the active circuitry side of the die and about the feature leaving the back side of the die exposed to lock the die in the encapsulant and/or to prevent moisture ingress.

14. The die package of claim 13 in which the feature is a ledge around the periphery of the die and the encapsulant is under the ledge.

15. The die package of claim 13 further including a lead frame about the die and wire bonds extending from the active circuitry side of the die to the lead frame, the encapsulant about the wire bonds and at least partially covering the lead frame.

16. An exposed die package comprising:
a die with an active circuitry side and a back side;
an encapsulant over the active circuitry side of the die but leaving the back side of the die exposed; and
means, on the side of the die, for locking the die in the encapsulant and/or for preventing moisture ingress along at least one side of the die.

17. The exposed die package of claim 16 in which said means is a ledge around the periphery of the die.
